(19) United States
(12) Patent Application Publication
(10) Pub. No.: US 2024/0369612 A1
(43) Pub. Date: Nov. 7, 2024

(54) MEASUREMENT SYSTEM FOR RADIO FREQUENCY MOS DEVICE MODELING AND MODELING METHOD FOR RADIO FREQUENCY MOS DEVICE

(71) Applicant: SHANGHAI IC R & D CENTER CO., LTD., Shanghai (CN)

(72) Inventors: Linlin LIU, Shanghai (CN); Yueyi FENG, Shanghai (CN); Quan WANG, Shanghai (CN)

(73) Assignee: SHANGHAI IC R & D CENTER CO., LTD., Shanghai (CN)

(21) Appl. No.: 18/689,838

(22) PCT Filed: Dec. 30, 2021
(86) PCT No.: PCT/CN2021/143035

§ 371 Date: Mar. 6, 2024

(30) Foreign Application Priority Data
Sep. 6, 2021 (CN) 202111040191.0

(51) Int. Cl. G01R 31/26

(52) U.S. Cl. CPC G01R 31/2601; G01R 31/2639

(57) ABSTRACT

The present invention provides a measurement system and modeling method for radio frequency MOS device modeling. Electrodes that are correspondingly provided in a slave test structure and a master test structure of the measurement system are different, where a source and a drain of a second MOS device are respectively connected to corresponding test ports, and a gate is independently connected out to facilitate setting a corresponding bias voltage. The modeling method configures an initial value of each parasitic element in a subcircuit model by means of a test result of the measurement system, corrects the initial values of at least some parasitic elements, and finally obtains parasitic parameter values of the parasitic elements.

### CROSS-REFERENCE TO RELATED DISCLOSURES

This application claims priority to Chinese Patent Disclosure No. 202111040191.0, filed on Sep. 6, 2021, which is hereby incorporated by reference in its entirety.

### TECHNICAL FIELD

The present disclosure relates to the technical field of a MOS device test and modeling. and in particular, to a measurement system for a radio frequency MOS device modeling and a modeling method for a radio frequency MOS device.

### RELATED ART

As the characteristic size of a transistor continues to shrink, the characteristic frequency (ft) and the maximum oscillation frequency (fmax) of MOS (Metal-Oxide-Semiconductor) devices continue to increase. Radio frequency (RF) MOS devices are beginning to be used in high-frequency fields such as millimeter waves and terahertz frequency bands. Accurate RF MOS device models need to be obtained for product development.

At present, in the high-frequency fields such as millimeter waves, the modeling of parasitic elements by the RF MOS device model is not accurate. A typical measurement system uses two ports structure to achieve a test, that is, a gate (Gate) and a drain (Drain) of the RF MOS device are used as two test terminals of the two ports structure, a source (Source) and a body (Body) are shorted circuited and grounded. This method can effectively extract parameters of the device model, but due to the short circuit between the source and the body, a parasitic capacitance between the source and the body, a parasitic capacitance between the gate and the body and a parasitic capacitance between the drain and the body cannot be accurately represented. Therefore, it is particularly necessary to further optimize the measurement system of the RF MOS device and improve the model accuracy of the RF MOS device.

### SUMMARY OF INVENTION

The invention provides a measurement system and a modeling method for a radio frequency MOS device, so as to improve the accuracy of a radio frequency MOS device model.

In order to achieve the above object, the present invention provides a measurement system for a radio frequency MOS device modeling. The measurement system includes a master test structure and a slave test structure, both the master test structure and the slave test structure use two ports for test; where the master test structure includes a first MOS device, a gate and a drain of the first MOS device are respectively connected to test ports of the master test structure, a source and a body of the first MOS device are short circuited and grounded; the slave test structure includes a second MOS device, a source and a drain of the second MOS device are respectively connected to test ports of the slave test structure, a gate of the second MOS device is independently connected out to facilitate setting a corresponding bias voltage, a body of the second MOS device is grounded.

In an implementation, the measurement system further includes a first de-embedding structure and a second de-embedding structure, the first de-embedding structure corresponds to the master test structure, and the second de-embedding structure corresponds to the slave test structure.

In an implementation, both the first de-embedding structure and the second de-embedding structure include an open circuit test substructure and a short circuit test substructure.

Another aspect of the present invention provides a modeling method for a radio frequency MOS device, the modeling method includes: providing the above-mentioned measurement system and constructing a subcircuit model, where the subcircuit model includes an intrinsic MOS device and multiple parasitic elements, the intrinsic MOS device has four electrodes, which are a source, a drain, a gate and a body, respectively, and the multiple parasitic elements include multiple parasitic capacitances; performing tests and de-embedding processing on the master test structure and the slave test structure respectively, so as to obtain a de-embedded S-parameter and current-voltage data of the master test structure and a de-embedded S-parameter of the slave test structure; setting an initial value of each parasitic element; using the de-embedded S-parameter of the slave test structure to correct at least part of the initial values of the multiple parasitic elements; and setting multiple parasitic parameter values of the multiple parasitic elements.

In an implementation, the measurement system further includes a first de-embedding structure and a second de-embedding structure, the first de-embedding structure corresponds to the master test structure, and the second de-embedding structure corresponds to the slave test structure; where the step of performing the tests and de-embedding processing on the master test structure and the slave test structure respectively specifically includes: performing S-parameter tests on the master test structure, the slave test structure, the first de-embedding structure and the second de-embedding structure respectively, to obtain respective corresponding S-parameters: processing the S-parameter of the master test structure based on the S-parameter of the first de-embedding structure to obtain the de-embedded S-parameter of the master test structure; and processing the S-parameter of the slave test structure based on the S-parameter of the second de-embedding structure to obtain the de-embedded S-parameter of the slave test structure.

In an implementation, the step of setting the initial value of each parasitic element includes: constructing an extraction layout structure of each parasitic capacitance based on a layout of a to-be-modeled radio frequency MOS device; and extracting an initial value of each parasitic capacitance based on the corresponding extraction layout structure by using a backend parasitic extraction tool.

In an implementation, the multiple parasitic capacitances include a gate-to-body parasitic capacitance Cgb formed between the gate and the body, a source-to-body parasitic capacitance Csb formed between the source and the body, and a drain-to-body parasitic capacitance Cdb formed between the drain and the body.

In an implementation, the step of constructing the extraction layout structures of each parasitic capacitance respectively includes: based on the layout of the radio frequency MOS device, reserving only a connection path for the gate and a connection path for the body to obtain an extraction layout structure of the gate-to-body parasitic capacitance Cgb, reserving only a connection path for the source and a connection path for the body to obtain an extraction layout structure of the source-to-body parasitic capacitance Csb, and reserving only a connection path for the drain and a connection path for the body to obtain an extraction layout structure of the drain-to-body parasitic capacitance Cdb.

In an implementation, the multiple parasitic elements further include: a drain-to-body parasitic resistance Rdb, a source-to-body parasitic resistance Rsb, a body parasitic resistance Rb, a draind parasitic resistance Rd, a source parasitic resistance Rs, a gate parasitic resistance Rg, a gate-to-drain parasitic capacitance Cgd, a gate-to-source parasitic capacitance Cgs, a drain-to-source parasitic capacitance Cds, a drain parasitic diode DD and a source parasitic diode DS.

In an implementation, the step of setting the initial value of each parasitic element further includes: substituting initial values of the gate-to-body parasitic capacitance Cgb, the source-to-body parasitic capacitance Csb and the drain-to-body parasitic capacitance Cdb into the subcircuit model, and determining initial values of the drain parasitic resistance Rd and the source parasitic resistance Rs by fitting the current-voltage data of the master test structure; converting the de-embedded S-parameter of the master test structure into a de-embedded Y-parameter and a de-embedded Z-parameter of the master test structure; and obtaining initial values of the drain-to-body parasitic resistance Rdb, the source-to-body parasitic resistance Rsb, the body parasitic resistance Rb, the gate parasitic resistance Rg, the gate-to-drain parasitic capacitance Cgd, the gate-to-source parasitic capacitance Cgs and the drain-to-source parasitic capacitance Cds by fitting different components of the de-embedded Y-parameter and the de-embedded Z-parameter of the master test structure.

In an implementation, the step of using the de-embedded S-parameter of the slave test structure to correct at least part of the initial values of the multiple parasitic elements includes: obtaining the de-embedded S-parameters under zero bias voltage of the source and the drain of the slave test structure; converting the de-embedded S-parameters under zero bias voltage into a de-embedded Y-parameter and a de-embedded Z-parameter of the slave test structure; and correcting at least part of the initial values of the multiple parasitic elements by fitting different components of the de-embedded Y-parameter and the de-embedded Z-parameter of the slave test structure.

In an implementation, the step of using the de-embedded S-parameter of the slave test structure to correct at least part of the initial values of the multiple parasitic elements includes: correcting iteratively at least part of the initial values of the multiple parasitic elements until convergence by repeatedly fitting the different components of the de-embedded Y-parameter and the de-embedded Z-parameter of the slave test structure.

In an implementation, after setting the multiple parasitic parameter values, the modeling method further includes: performing iteratively from the step of setting the initial values of the multiple parasitic elements to the step of setting the multiple parasitic parameter values, and using the multiple parasitic parameter values to perform a simulation test on the subcircuit model until a fitting error between a simulation result of the subcircuit model and test data of the master test structure is within a corresponding setting range, and a fitting error between the simulation result of the subcircuit model and test data of the slave test structure is also within a corresponding setting range.

The measurement system for the radio frequency MOS device modeling of the present invention uses both the master test structure and the slave test structure to model the radio frequency MOS device, which can improve the accuracy and expand the applicability of the radio frequency MOS device model.

The modeling method for the radio frequency MOS device of the present invention can correct the initial values of the parasitic elements, which helps to improve the accuracy of the parasitic parameter values of the parasitic elements, and improve the accuracy and disclosure range of the radio frequency MOS device model.

### BRIEF DESCRIPTION OF DRAWINGS

FIG. 1 is a layout structure schematic diagram of an existing MOS device.

FIG. 2 is a subcircuit model schematic diagram of an existing radio frequency MOS device.

FIG. 3 is a schematic diagram of a master test structure of a measurement system in an embodiment of the present disclosure.

FIG. 4 is a schematic diagram of a slave test structure of a measurement system in an embodiment of the present disclosure.

FIG. 5 is a flowchart of a modeling method for a radio frequency MOS device in an embodiment of the present disclosure.

FIG. 6 is a schematic diagram of a subcircuit model of a radio frequency MOS device in an embodiment of the present disclosure.

FIG. 7 is a schematic diagram of an extraction layout structure of a gate-to-body parasitic capacitance Cgb in an embodiment of the present disclosure.

FIG. 8 is a circuit schematic diagram of an extraction layout structure of a gate-to-body parasitic capacitance Cgb in an embodiment of the present disclosure.

FIG. 9 is a schematic diagram of an extraction layout structure of a drain-to-body parasitic capacitance Cdb and a source-to-body parasitic capacitance Csb in an embodiment of the present disclosure.

FIG. 10 is a circuit schematic diagram of an extraction layout structure of a drain-to-body parasitic capacitance Cdb and a source-to-body parasitic capacitance Csb in an embodiment of the present disclosure.

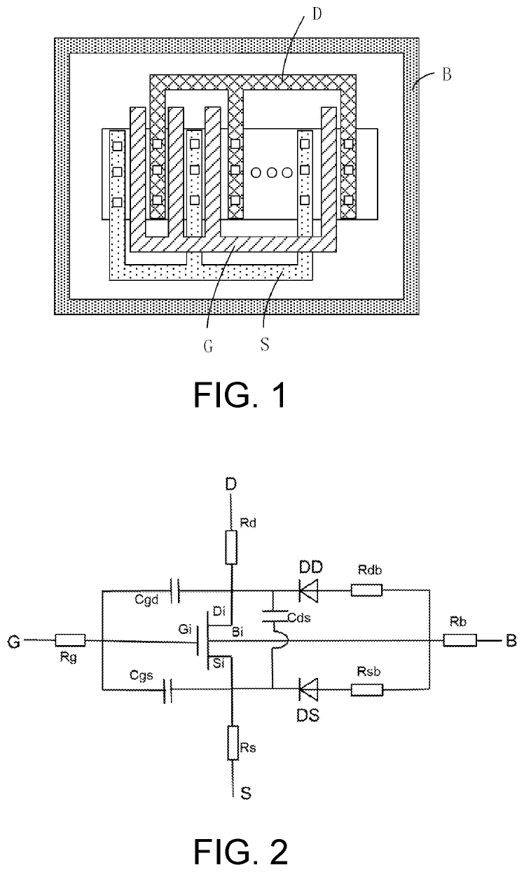

### DESCRIPTION OF EMBODIMENTS

A measurement system for a radio frequency MOS device modeling and a modeling method for a radio frequency MOS device proposed by the present invention will be further described in detail below in conjunction with the accompanying drawings and specific embodiments. The advantages and features of the present invention will become clearer from the following description. It should be noted that all the drawings are in a very simplified form and use imprecise scales, and are only used to facilitate and clearly assist the purpose of illustrating embodiments of the present invention.

### First Embodiment

This embodiment provides a measurement system for a radio frequency MOS device modeling, the measurement system includes a master test structure and a slave test structure, both the master test structure and the slave test structure use two ports for test.

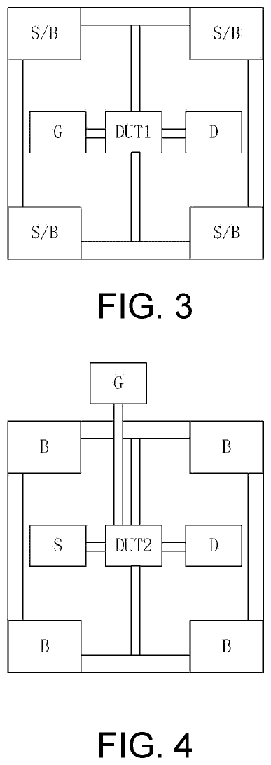

FIG. 3 is a schematic diagram of a master test structure of a measurement system in an embodiment of the present disclosure. As shown in FIG. 3, the master test structure has two test ports and includes a first MOS device (denoted as DUT1). A gate (G) and a drain (D) of the first MOS device are respectively connected to the test ports of the master test structure, and a source (S) and a body (B) of the first MOS device are short circuited and grounded.

FIG. 4 is a schematic diagram of a slave test structure of a measurement system in an embodiment of the present disclosure. As shown in FIG. 4, the slave test structure has two test ports and includes a second MOS device (denoted as DUT2). A source (S) and a drain (D) of the second MOS device are respectively connected to corresponding test ports, a gate (G) of the second MOS device is independently connected out to facilitate setting a corresponding bias voltage, a body (B) of the second MOS device is grounded.

The master test structure is used to test and obtain current-voltage data and a corresponding S-parameter within a working frequency range, and the slave test structure is used to test and obtain a corresponding S-parameter within the working frequency range, and the current-voltage data includes output characteristic data and/or transfer characteristic data of the radio frequency MOS device under different gate-to-source bias voltages.

Layouts and sizes of the first MOS device and the second MOS device are the same as layouts and sizes of a to-be-modeled radio frequency MOS device.

The measurement system may further include a first de-embedding structure and a second de-embedding structure. The first de-embedding structure corresponds to the master test structure, and the second de-embedding structure corresponds to the slave test structure. Both the first de-embedding structure and the second de-embedding structure can include an open circuit test substructure (an open structure) and a short circuit test substructure (a short structure). In this embodiment, an S-parameter of the first de-embedding structure is used to perform de-embedding processing on an S-parameter of the master test structure and obtain a de-embedded S-parameter of the master test structure; and the second de-embedding structure is used to perform de-embedding processing on an S-parameter of the slave test structure and obtain a de-embedded S-parameter of the slave test structure.

In this embodiment, the slave test structure adopts different electrode settings from the master test structure (that is, the connection modes of the electrodes are different), where the source (S) and the drain (D) of the second MOS device are respectively connected to the test ports of the slave test structure, the gate (G) of the second MOS device is independently connected out to facilitate setting a corresponding bias voltage, the body (B) of the second MOS device is grounded. That is, due to the fact that the source and the body of the second MOS device are not short circuited, and the gate is independently connected out, the S-parameter of the slave test structure can represent parasitic capacitances which cannot be represented by the master test structure (such as a gate-to-body parasitic capacitance Cgb, a source-to-body parasitic capacitance Csb and a drain-to-body parasitic capacitance Cdb).

### Second Embodiment

In the prior art, a source and a body are short circuited, a parasitic capacitance between the source and the body, a parasitic capacitance between a gate and a body and a parasitic capacitance between a drain and a body cannot be accurately represented, which affects the numerical accuracy of other parasitic capacitances and parasitic resistances.

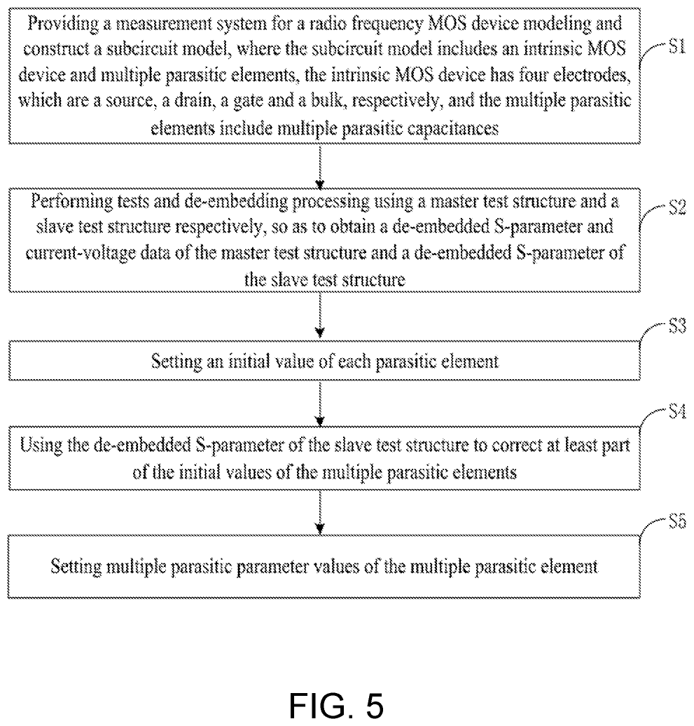

FIG. 5 is a flowchart of a modeling method for a radio frequency MOS device in an embodiment of the present disclosure. As shown in FIG. 5, the modeling method for the radio frequency MOS device includes the following steps.

S1: Providing a measurement system for the radio frequency MOS device and construct a subcircuit model.

The measurement system of this embodiment is the same as that of the first embodiment.

Specifically, as shown in FIG. 3, the master test structure includes the first MOS device (denoted as DUT1). The gate (G) and the drain (D) of the first MOS device are respectively connected to test ports of the master test structure, the source (S) and the body (B) are short circuited and grounded.

In order to accurately represent the parasitic capacitance, the subcircuit model includes multiple parasitic elements, the multiple parasitic elements include multiple parasitic capacitances, and the multiple parasitic capacitances include a gate-to-body parasitic capacitance Cgb formed between the gate and the body, a source-to-body parasitic capacitance Csb formed between the source and the body, and a drain-to-body parasitic capacitance Cdb formed between the drain and the body.

In this embodiment, the measurement system is additionally provided with a slave test structure. As shown in FIG. 4, the slave test structure includes the second MOS device (denoted as DUT2), an electrode connection mode of the second MOS device is different from that of the first MOS device, the source and the drain of the second MOS device are respectively connected to test ports of the slave test structure, the gate is independently connected out (that is, not short circuited to any one of the source, the drain, and the body) to facilitate setting the corresponding bias voltage, the body is grounded, so that the S-parameter of the slave test structure can be obtained to represent each parasitic capacitance mentioned above. In the subsequent modeling, the parasitic capacitances are added in calculation of the subcircuit model, to improve the accuracy of the radio frequency MOS model.

The measurement system further includes a first de-embedding structure and a second de-embedding structure, the first de-embedding structure corresponds to the master test structure, and the second de-embedding structure corresponds to the slave test structure.

In this embodiment, the step S1 further includes constructing the subcircuit model, the subcircuit model includes an intrinsic MOS device and multiple parasitic elements, the intrinsic MOS device has four electrodes, which are a source, a drain, a gate and a body, respectively, and the multiple parasitic elements include the parasitic capacitances mentioned above.

The layouts and sizes of the intrinsic MOS device, the first MOS device and the second MOS device are the same as the layouts and sizes of a to-be-modeled radio frequency MOS device.

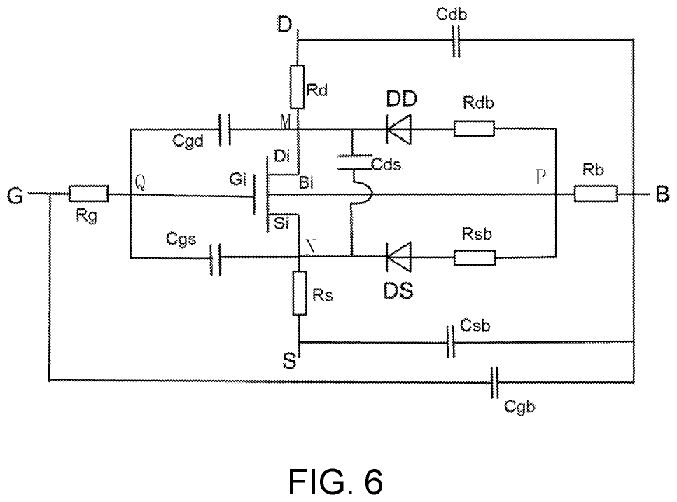

FIG. 6 is a schematic diagram of a subcircuit model of a radio frequency MOS device in an embodiment of the present disclosure. As shown in FIG. 6, on the basis of the subcircuit model constructed in the step S1, this embodiment not only includes the parasitic elements shown in FIG. 2, but also at least includes the parasitic capacitances.

As shown in FIG. 6, in the subcircuit model constructed in the step S1 of this embodiment, the intrinsic MOS device has four electrodes, which are the source (Si), the drain (Di), the gate (Gi), and the body (Bi), respectively. One end of a gate-to-drain parasitic capacitance Cgd, one end of a drain-to-source parasitic capacitance Cds, and one end of a drain parasitic diode DD are all connected to a node M; one end of a gate-to-source parasitic capacitance Cgs, the other end of the drain-to-source parasitic capacitance Cds, and one end of a source parasitic diode DS are all connected to a node N; one end of a body parasitic resistance Rb, one end of a drain-to-body parasitic resistance Rdb, and a source-to-body parasitic resistance Rsb are all connected to a node P; the other end of the gate-drain parasitic capacitance Cgd and the other end of the gate-source parasitic capacitance Cgs are all connected to a node Q; the other end of the drain parasitic diode DD is connected to the other end of the drain-to-body parasitic resistance Rdb, the other end of the source parasitic diode DS is connected to the other end of the source-to-body parasitic resistance Rsb.

In addition, the subcircuit model is also provided with a drain port (D), a body port (B), a source port (S) and a gate port (G). One end of a drain parasitic resistance Rd is connected to the node M, and the other end of the drain parasitic resistance Rd is connected to the drain port; one end of a drain parasitic resistance Rd is connected to the node P, and the other end of the drain parasitic resistance Rd is connected to the body port; one end of a gate parasitic resistance Rg is connected to the node Q, and the other end of the gate parasitic resistance Rg is connected to the gate port; one end of a body parasitic resistance Rb is connected to the node N, and the other end of the body parasitic resistance Rb is connected to the source port; two ends of the drain-to-body parasitic capacitance Cdb are respectively connected to the drain port and the body port; two ends of the source-to-body parasitic capacitance Csb are respectively connected to the body port and the source port S; the gate-to-body parasitic capacitance Cgb is respectively connected to the gate port and the body port.

S2: Performing tests and corresponding de-embedding processing on the master test structure and the slave test structure respectively, so as to obtain a de-embedded S-parameter and current-voltage data of the master test structure within a working frequency range and a de-embedded S-parameter of the slave test structure within the working frequency range. In this embodiment, the working frequency ranges of the first MOS device and the second MOS device may be 0 GHZ-100 GHZ. The working frequency ranges of the intrinsic MOS device, the first MOS device and the second MOS device are the same as the working frequency range of the to-be-modeled MOS device. When performing tests on the master test structure and the slave test structure, the test frequency range may be within the working frequency range.

In this embodiment, existing technology can be used to perform S-parameter tests on each test structure in the measurement system, so as to obtain the S-parameter of each test structure and the current-voltage data of the master test structure.

The step S2 may specifically include: at first, performing S-parameter tests on the master test structure, the slave test structure, the first de-embedding structure and the second de-embedding structure respectively, to obtain corresponding S-parameters; processing (operating) the S-parameter of the master test structure based on the S-parameter of the first de-embedding structure to obtain the de-embedded S-parameter of the master test structure; and processing (operating) the S-parameter of the slave test structure based on the S-parameter of the second de-embedding structure to obtain the de-embedded S-parameter of the slave test structure. Using the de-embedded S-parameters of the master test structure and the slave test structure to model the RF MOS device helps to improve the accuracy of the RF MOS device model.

Specifically, both the first de-embedding structure and the second de-embedding structure can include an open circuit test substructure (i.e. an open structure) and a short circuit test substructure (i.e. a short structure). As an example, at first, the S-parameter test is performed on the master test structure and its open circuit test substructure a and short circuit test substructure b respectively to obtain the corresponding S-parameters; then, according to an open circuit-short circuit (open-short) de-embedding method, the master test structure is de-embedded to obtain the de-embedded S-parameter of the master test structure; and then, the S-parameter test is performed on the slave test structure and its open circuit test substructure c and short circuit test substructure d respectively to obtain corresponding S-parameters; then, according to the open circuit-short circuit (open-short) de-embedding method, the slave test structure is de-embedded to obtain the de-embedded S-parameter of the slave test structure.

S3: Setting an initial value of each parasitic element.

It specifically includes the following contents.

In the first sub-step, determining models and size parameters of the intrinsic MOS device, the drain parasitic diode DD, and the source parasitic diode DS of the subcircuit model.

In this embodiment, selecting the models of the intrinsic MOS device, the drain parasitic diode DD and the source parasitic diode DS according to the manufacturing process of the to-be-modeled radio frequency MOS device; determining the size parameters of the intrinsic MOS device, the drain parasitic diode DD and the source parasitic diode DS according to layout sizes of a channel and a source-to-drain region of the to-be-modeled radio frequency MOS device.

In the second sub-step, constructing an extraction layout structure of each parasitic capacitance based on a layout of the to-be-modeled radio frequency MOS device; and extracting an initial value of each parasitic capacitance based on the corresponding extraction layout structure by using a backend parasitic extraction tool.

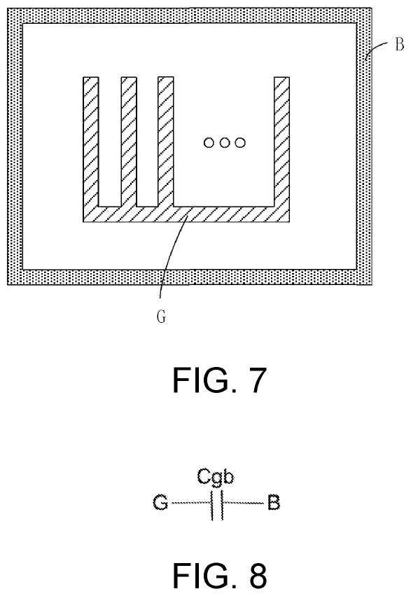

Specifically, an extraction layout structure of the gate-to-body parasitic capacitance Cgb is shown in FIG. 7. A circuit of the extraction layout structure of the gate-to-body parasitic capacitance Cgb is shown in FIG. 8. As shown in FIG. 7 and FIG. 8, based on the layout of the radio frequency MOS device, only a connection path for the gate (G) and a connection path for the body (B) are reserved to obtain the extraction layout structure of the gate-to-body parasitic capacitance Cgb.

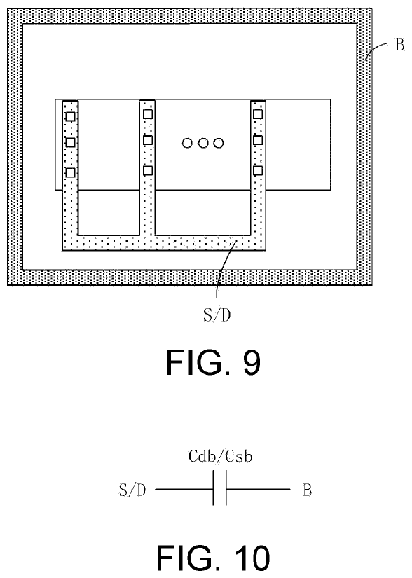

An extraction layout structure of the drain-to-body parasitic capacitance Cdb and the source-to-body parasitic capacitance Csb is shown in FIG. 9. A circuit of the extraction layout structure of the drain-to-body parasitic capacitance Cdb and the source-to-body parasitic capacitance Csb is shown in FIG. 10. As shown in FIG. 9 and FIG. 10, based on the layout of the radio frequency MOS device, only a connection path for the source (S) and a connection path for the body (B) are reserved to obtain the extraction layout structure of the source-to-body parasitic capacitance Csb, and only a connection path for the drain (D) and a connection path for the body (B) are reserved to obtain the extraction layout structure of the drain-to-body parasitic capacitance Cdb.

In this embodiment, the initial value of each parasitic capacitance is extracted by using a conventional backend parasitic extraction tool in the field, and the backend parasitic extraction tool is not limited here.

In the third sub-step, substituting the initial values of the parasitic capacitances into the subcircuit model constructed in step S1.

In this embodiment, based on the model of the intrinsic MOS device, determining initial values of the drain parasitic resistance Rd and the source parasitic resistance Rs by fitting the current-voltage data of the master test structure; converting the de-embedded S-parameter of the master test structure into a de-embedded Y-parameter and a de-embedded Z-parameter of the master test structure; obtaining initial values of the drain-to-body parasitic resistance Rdb, the source-to-body parasitic resistance Rsb, the body parasitic resistance Rb, the gate parasitic resistance Rg, and the parasitic capacitances by fitting different components of the de-embedded Y-parameter and the de-embedded Z-parameter of the master test structure.

In the third sub-step, the de-embedded S-parameter of the master test structure can be converted into the de-embedded Y-parameter and the de-embedded Z-parameter of the master test structure; under zero bias voltage conditions and within the test frequency range (for example, the test frequency range is the working frequency range of the to-be-modeled radio frequency MOS device), the initial values of the parasitic capacitances can be determined by fitting imaginary parts of components Y11, Y21, Y22 of the de-embedded Y-parameter of the master test structure; the initial value of the gate parasitic resistance Rg can be determined by fitting real parts of the component Y11 of the de-embedded Y-parameter and a component Z11 of the de-embedded Z-parameter of the master test structure within the test frequency range; the initial values of the body parasitic resistance Rb, the source-to-body parasitic resistance Rsb, and the drain-to-body parasitic resistance Rdb can be determined by fitting real parts of the component Y22 of the de-embedded Y-parameter and a component Z22 of the de-embedded Z-parameter of the master test structure. Here, the S-parameter (scattering parameter), the Y-parameter (admittance parameter) and Z-parameter (impedance parameter) are all matrix parameters; Y11 is a value of a first row and a first column of a de-embedded Y-parameter matrix of the master test structure; Y21 is a value of a second row and a first column of the de-embedded Y-parameter matrix of the master test structure; Y22 is a value of a second row and a second column of the de-embedded Y-parameter matrix of the master test structure; Z11 is a value of a first row and a first column of a de-embedded Z-parameter matrix of the master test structure; Z22 is a value of a second row and a second column of the de-embedded Z-parameter matrix of the master test structure.

The third sub-step may further include: correcting iteratively the initial values of the gate-to-source parasitic capacitance Cgs, the gate-to-drain parasitic capacitance Cgd, the gate-to-body parasitic capacitance Cgb, the drain-to-body parasitic capacitance Cdb, the gate parasitic resistance Rg. the drain parasitic resistance Rd, the source parasitic resistance Rs, the body parasitic resistance Rb and the drain-to-body parasitic resistance Rdb until convergence by repeatedly fitting the components of the de-embedded Y-parameter and the de-embedded Z-parameter of the master test structure, which helps to improve the accuracy of the obtained RF MOS device model.

S4: Using the de-embedded S-parameter of the slave test structure to correct at least part of the initial values of the multiple parasitic elements.

The step S4 specifically includes: at first, obtaining the de-embedded S-parameters under zero bias voltage of the source and the drain of the slave test structure; then, under zero bias voltage, converting the de-embedded S-parameters of the slave test structure into a de-embedded Y-parameter and a de-embedded Z-parameter of the slave test structure; and correcting at least part of the initial values of the multiple parasitic elements by fitting different components of the de-embedded Y-parameter and the de-embedded Z-parameter of the slave test structure.

Specifically, the initial values of the parasitic capacitances are corrected based on imaginary parts of the components Y11, Y21, Y22 of the de-embedded Y-parameter of the slave test structure; the initial values of the drain-to-body parasitic resistance Rdb, the source-to-body parasitic resistance Rsb, the body parasitic resistance Rb, the source parasitic resistance Rs and the drain parasitic resistance Rd are corrected based on the imaginary parts of the components Y11, Y21, Y22 of the de-embedded Y-parameter of the slave test structure and real parts of components Z11, Z22 of the de-embedded z-parameter of the slave test structure. Here, the S-parameter, the Y-parameter and Z-parameter are all matrix parameters; Y11 is a value of a first row and a first column of a de-embedded Y-parameter matrix of the slave test structure; Y21 is a value of a second row and a first column of the de-embedded Y-parameter matrix of the slave test structure; Y22 is a value of a second row and a second column of the de-embedded Y-parameter matrix of the slave test structure; Z11 is a value of a first row and a first column of a de-embedded Z-parameter matrix of the slave test structure; Z22 is a value of a second row and a second column of the de-embedded Z-parameter matrix of the slave test structure.

In this embodiment, the step S4 may further include: correcting iteratively at least part of the initial values of the multiple parasitic elements until convergence by repeatedly fitting the different components of the de-embedded Y-parameter and the de-embedded Z-parameter of the slave test structure.

S5: Setting multiple parasitic parameter values of the multiple parasitic elements. In other words, the step S5 of this embodiment is: obtaining or determining the parasitic parameter values of the parasitic elements in the subcircuit model constructed in step S1.

In this embodiment, after setting the multiple parasitic parameter values, the modeling method of this embodiment may further include: performing iteratively from the step of setting the initial values of the multiple parasitic elements (i.e. S3) to the step of setting the multiple parasitic parameter values (i.e. perform iteratively from S3 to S5), and using the multiple parasitic parameter values to perform a simulation test on the subcircuit model constructed in S1 until a fitting error between a simulation result of the subcircuit model and test data of the master test structure is within a corresponding setting range, and a fitting error between the simulation result of the subcircuit model and test data of the slave test structure is also within a corresponding setting range.

In this embodiment, after determining the multiple parasitic parameter values of the multiple parasitic elements in the subcircuit model constructed in step S1, the radio frequency MOS device model can be obtained.

The measurement system of this embodiment can also be used to correct the initial values of the parasitic elements in the subcircuit model by using the S-parameter of the slave test structure, which helps to improve the accuracy of the parameter values of the parasitic elements, and improve the accuracy and disclosure range of the obtained radio frequency MOS device model.

The above description is only a description of the preferred embodiments of the present invention, and is not any limitation to the scope of rights of the present invention. Any person skilled in the art may use the methods and technical contents disclosed above to make possible changes and modifications to the technical solution of the present invention without departing from the spirit and scope of the present invention. Therefore, any simple modification, equivalent change and modification made to the above embodiments according to the technical essence of the present invention, which do not depart from the content of the technical solution of the present invention, all belong to the protection range of the technical solution of the present invention.

1. A measurement system for a radio frequency MOS device modeling, comprising a master test structure and a slave test structure, both the master test structure and the slave test structure use two ports for test; wherein the master test structure comprises a first MOS device, a gate and a drain of the first MOS device are respectively connected to test ports of the master test structure, a source and a body are short circuited and grounded; the slave test structure comprises a second MOS device, a source and a drain of the second MOS device are respectively connected to test ports of the slave test structure, a gate is independently connected out to facilitate setting a corresponding bias voltage, a body of the second MOS device is grounded.

2. The measurement system according to claim 1, further comprising a first de-embedding structure and a second de-embedding structure, the first de-embedding structure corresponds to the master test structure, and the second de-embedding structure corresponds to the slave test structure.

3. The measurement system according to claim 2, wherein both the first de-embedding structure and the second de-embedding structure comprise an open circuit test substructure and a short circuit test substructure.

4. A modeling method for a radio frequency MOS device, comprising:
providing the measurement system according to claim 1 and constructing a subcircuit model, wherein the subcircuit model comprises an intrinsic MOS device and multiple parasitic elements, the intrinsic MOS device has four electrodes, which are a source, a drain, a gate and a body, respectively, and the multiple parasitic elements comprise multiple parasitic capacitances;
performing tests and de-embedding processing on the master test structure and the slave test structure respectively, so as to obtain a de-embedded S-parameter and current-voltage data of the master test structure and a de-embedded S-parameter of the slave test structure;
setting an initial value of each parasitic element;
using the de-embedded S-parameter of the slave test structure to correct at least part of the initial values of the multiple parasitic elements; and
setting multiple parasitic parameter values of the multiple parasitic elements.

5. The modeling method according to claim 4, wherein the measurement system further comprises a first de-embedding structure and a second de-embedding structure, the first de-embedding structure corresponds to the master test structure, and the second de-embedding structure corresponds to the slave test structure.

6. The modeling method according to claim 4, wherein the method of setting the initial value of each parasitic element comprises:
constructing an extraction layout structure of each parasitic capacitance respectively based on a layout of a to-be-modeled radio frequency MOS device; and
extracting an initial value of each parasitic capacitance respectively based on the corresponding extraction layout structure by using a backend parasitic extraction tool.

7. The modeling method according to claim 6, wherein the multiple parasitic capacitances comprise a gate-to-body parasitic capacitance Cgb formed between the gate and the body, a source-to-body parasitic capacitance Csb formed between the source and the body, and a drain-to-body parasitic capacitance Cdb formed between the drain and the body.

8. The modeling method according to claim 7, wherein the method of constructing the extraction layout structure of each parasitic capacitance respectively comprises:
based on the layout of the radio frequency MOS device, reserving only a connection path for the gate and a connection path for the body to obtain an extraction layout structure of the gate-to-body parasitic capacitance Cgb, reserving only a connection path for the source and a connection path of the body to obtain an extraction layout structure of the source-to-body parasitic capacitance Csb, and reserving only a connection path for the drain and a connection path for the body to obtain an extraction layout structure of the drain-to-body parasitic capacitance Cdb.

9. The modeling method according to claim 8, wherein the multiple parasitic elements further comprise: a drain-to-body parasitic resistance Rdb, a source-to-body parasitic resistance Rsb, a body parasitic resistance Rb, a drain parasitic resistance Rd, a source parasitic resistance Rs, a gate parasitic resistance Rg, a gate-to-drain parasitic capacitance Cgd, a gate-to-source parasitic capacitance Cgs, a drain-to-source parasitic capacitance Cds, a drain parasitic diode DD and a source parasitic diode DS.

10. The modeling method according to claim 9, wherein the step of setting the initial value of each parasitic element further comprises:
substituting initial values of the gate-to-body parasitic capacitance Cgb, the source-to-body parasitic capacitance Csb and the drain-to-body parasitic capacitance Cdb into the subcircuit model, and determining initial values of the drain parasitic resistance Rd and the source parasitic resistance Rs by fitting the current-voltage data of the master test structure;
converting the de-embedded S-parameter of the master test structure into a de-embedded Y-parameter and a de-embedded Z-parameter of the master test structure; and
obtaining initial values of the drain-to-body parasitic resistance Rdb, the source-to-body parasitic resistance Rsb, the body parasitic resistance Rb, the gate parasitic resistance Rg, the gate-to-drain parasitic capacitance Cgd, the gate-to-source parasitic capacitance Cgs and the drain-to-source parasitic capacitance Cds by fitting different components of the de-embedded Y-parameter and the de-embedded Z-parameter of the master test structure.

11. The modeling method according to claim 4, wherein the step of using the de-embedded S-parameter of the slave test structure to correct at least part of the initial values of the multiple parasitic elements comprises:
obtaining the de-embedded S-parameters under zero bias voltage of the source and the drain of the slave test structure;
converting the de-embedded S-parameters under zero bias voltage into a de-embedded Y-parameter and a de-embedded Z-parameter of the slave test structure; and
correcting at least part of the initial values of the multiple parasitic elements by fitting different components of the de-embedded Y-parameter and the de-embedded Z-parameter of the slave test structure.

12. The modeling method according to claim 11, wherein the step of correcting at least part of the initial values of the multiple parasitic elements by fitting different components of the de-embedded Y-parameter and the de-embedded Z-parameter of the slave test structure comprises: correcting iteratively at least part of the initial values of the multiple parasitic elements until convergence by repeatedly fitting the different components of the de-embedded Y-parameter and the de-embedded Z-parameter of the slave test structure.

13. The modeling method according to claim 4, wherein after setting the multiple parasitic parameter values, the modeling method further comprises:
performing iteratively from the step of setting the initial values of the multiple parasitic elements to the step of setting the multiple parasitic parameter values, and using the multiple parasitic parameter values to perform a simulation test on the subcircuit model until a fitting error between a simulation result of the subcircuit model and test data of the master test structure is within a corresponding setting range, and a fitting error between the simulation result of the subcircuit model and test data of the slave test structure is also within a corresponding setting range.

14. The modeling method according to claim 5, wherein both the first de-embedding structure and the second de-embedding structure comprise an open circuit test substructure and a short circuit test substructure.

15. The modeling method according to claim 5, wherein the step of performing the tests and the de-embedding processing on the master test structure and the slave test structure respectively specifically comprises: performing S-parameter tests on the master test structure, the slave test structure, the first de-embedding structure and the second de-embedding structure respectively, to obtain corresponding S-parameters; processing the S-parameter of the master test structure based on the S-parameter of the first de-embedding structure to obtain the de-embedded S-parameter of the master test structure; and processing the S-parameter of the slave test structure based on the S-parameter of the second de-embedding structure to obtain the de-embedded S-parameter of the slave test structure.
